(19) United States
(12) Patent Application Publication
(10) Pub. No.: US 2012/0146064 A1
(43) Pub. Date: Jun. 14, 2012

(54) DEPOSITION MASK AND METHOD OF MANUFACTURING ORGANIC EL DISPLAY PANEL INCORPORATING DEPOSITION MASK

(75) Inventor: Nobuyuki Ishikawa, Sanbu-gun (JP)

(73) Assignee: CANON KABUSHIKI KAISHA, Tokyo (JP)

(21) Appl. No.: 13/312,855

(22) Filed: Dec. 6, 2011

(30) Foreign Application Priority Data
Dec. 10, 2010 (JP) 2010-276175

(51) Int. Cl. H01L 51/52; B05C 11/00; H01L 51/56

(52) U.S. Cl. 257/88; 438/34; 118/504; 257/40; 257/E51.018

(57) ABSTRACT

A deposition mask used in the manufacture of an organic EL display panel. A sheet of mask foil provided with a plurality of slit-shaped openings is fixed to a mask frame. Ends of successively arranged at least three openings are displaced from one another along the longitudinal direction of the openings.

### BACKGROUND OF THE INVENTION

1. Field of the Invention

The present invention relates to a deposition mask used for vapor deposition. More particularly, the present invention relates to a deposition mask which is provided with slit-shaped openings and is used in the manufacture of an organic EL display device.

2. Description of the Related Art

A deposition mask is used widely in the manufacture of a display device in which an organic EL device is incorporated. Such a deposition mask is constituted by a sheet of metal mask foil provided with openings for the selective formation of organic compound layers of red (R), green (G) and blue (B). In order to address the recent increasing demand for high-resolution display devices, a tension mask has become predominant in which a sheet of mask foil provided with a precisely dimensioned opening pattern is fixed to a frame under tension.

A deposition mask with a slit-shaped opening pattern is disclosed in Japanese Patent No. 4173722 (Patent Document 1). In the deposition mask disclosed in Patent Document 1, the same slit-shaped openings are arranged at a regular pitch with ends thereof aligned one another. The deposition mask of Patent Document 1 has the following deficiency: external force, applied to the deposition mask during conveyance of the deposition mask before and after the formation of layers or during alignment with a substrate, may cause vibration in foil sections defined between adjoining slit-shaped openings (hereinafter, the sections will be referred to as “ribs”) and, as a result, the ribs come in close contact with one another and block the openings. As the amount of deposition material deposit on the deposition mask increases, vibration becomes strong and therefore the slit-shaped openings are blocked more easily.

In order to prevent such deformation of the ribs, Japanese Patent Laid-Open No. 2003-332059 (Patent Document 2) proposes a reduction in deformation of a mask by providing bridges at several locations of slit-shaped openings, and arranging the openings, which are partitioned by the bridges, to be aligned alternately on odd and even lines.

In the deposition mask of Patent Document 1, since adjoining ribs are the same in shape and arrangement, external force applied to the ribs during, for example, conveyance eventually causes the same steady state vibration in all the ribs. Under steady state vibration, adjoining ribs are the same in amplitude and node position of vibration. Therefore, the ribs which came in close contact with one another before the external force eventually causes steady state vibration do not separate from one another due to the same repeated vibration in the steady state vibration.

In the deposition mask of Patent Document 2 provided with the bridges, the foil sections are not easily deformed due to vibration; but it is necessary to determine areas in which organic compound layer are to be formed, i.e., to determine an arrangement of pixels (light emitting units), in consideration of the bridge positions. In addition to that, the bridges provided in the deposition mask reduce areas in which pixels may be arranged and thereby a light emission area is decreased. This may cause an increase in power consumption and shortening of life of the deposition mask as compared with a configuration provided with no bridges.

### SUMMARY OF THE INVENTION

The present invention is a deposition mask in which a sheet of mask foil provided with a plurality of slit-shaped openings is fixed to a mask frame, wherein ends of successively arranged at least three openings are displaced from one another along the longitudinal direction of the openings.

In addition, the present invention is a method of manufacturing an organic EL display panel, including: forming a driving circuit on a substrate; and forming an organic emitting layer on the substrate using the deposition mask.

The deposition mask according to the present invention has wide openings corresponding to vapor deposition areas and prevents a plurality of slit-shaped openings from being blocked by foil sections in contact with one another due to vibration. An organic EL display panel with a large light emission area is manufactured at high yield using the deposition mask according to the present invention.

Further features of the present invention will become apparent from the following description of exemplary embodiments with reference to the attached drawings.

### BRIEF DESCRIPTION OF THE DRAWINGS

FIGS. 1A and 1B illustrate a deposition mask according to the present invention and a deposition mask used in a first example.

FIG. 2 illustrates openings formed in a deposition mask used in a second example.

FIG. 3 illustrates openings formed in a related art deposition mask.

### DESCRIPTION OF THE EMBODIMENTS

An embodiment according to the present invention will be described with reference to the drawings. The drawings are not to scale.

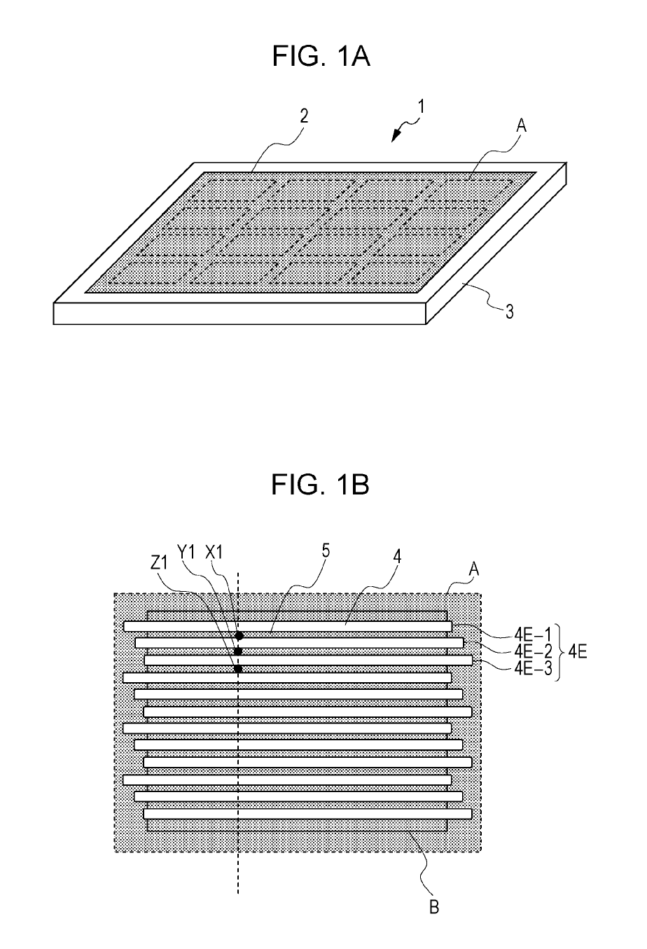

FIGS. 1A and 1B illustrate a deposition mask 1 according to the present invention, which is an exemplary deposition mask suitably used in the manufacture of a plurality of organic EL display panels from a single substrate. FIG. 1A is a perspective view seen from a side of a sheet of mask foil 2. The deposition mask 1 is fixed to a mask frame 3 by means of, for example, welding under tension applied to the sheet of mask foil 2. The sheet of mask foil 2 has areas A, each of which corresponds to a single organic EL display panel. Each area A includes slit-shaped openings for the selective formation of organic compound layers.

FIG. 1B is an enlarged plan view of one of the areas A. Each area A has slit-shaped openings (hereinafter, “opening”) 4 of the same length; sections defined between adjoining openings 4 are referred to as ribs 5. Desirably, tension is applied to the sheet of mask foil 2 such that a tension component along the width direction of the opening 4 does not cause deformation in ends 4 of the slit-shaped openings (“opening ends 4E”). Tension is greater in the longitudinal direction than in the width direction of the openings 4. An area B corresponds to an image display area of the organic EL display panel. The opening ends 4E are situated outside the image display area.

As illustrated in FIG. 1B, opening ends 4E-1, 4E-2 and 4E-3 of at least three successively arranged openings 4 are displaced from one another at both ends of the openings 4 along the longitudinal direction of the openings 4. This configuration allows the node positions of steady state vibration (natural vibration) produced in the adjoining ribs 5 by the external force to differ from one another.

In a normal tension mask, the width of the rib 5 is greater than the thickness of the sheet of mask foil 2; therefore, vibration of the ribs 5 is stronger in the normal direction (i.e., the gravity direction) of the surface of the sheet of mask foil 2 among other directions. The amounts of displacement of points X1, Y1 and Z1 arranged in the width direction of the three adjoining ribs 5 in the normal direction of a surface of the sheet of mask foil 2 by vibration are different from one another because steady state vibration is eventually caused in the ribs 5. Then, if X1 and Y1 or Y1 and Z1 come in close contact with each other, force to separate X1 from Y1 or separate Y1 from Z1 is exerted. This means that, even if X1 and Y1 or Y1 and Z1 come in close contact with each other, it is possible to eventually separate X1 from Y1 or separate Y1 from Z1.

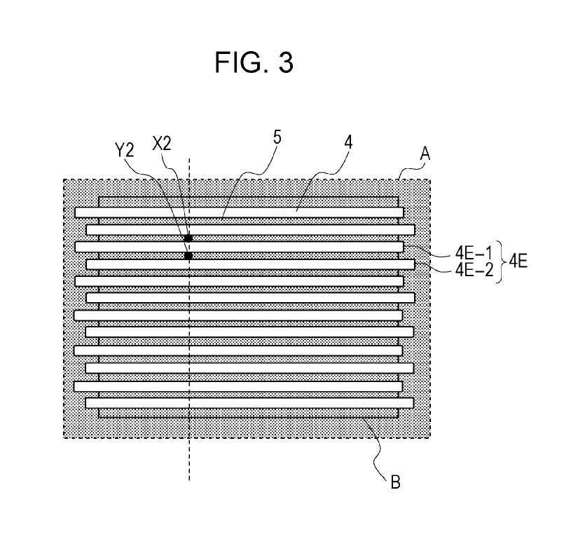

An area A of a deposition mask 1 in which only positions of opening ends 4E-1 and 4E-2 of two successively arranged openings 4 differ from each other is illustrated in FIG. 3. Since adjoining ribs 5 are symmetrical to each other about the opening 4 therebetween and the same steady state vibration is caused in both of them, the amounts of displacement of proximal points X2 and Y2 of adjoining ribs 5 in the normal direction of a surface of the sheet of mask foil 2 are the same. Then, the points X2 and Y2 once come in close contact with each other under external force do not separate from each other due to the same, eventually caused repeated steady state vibration. If layers are formed using the deposition mask 1 of which openings are blocked by the adjoining ribs 5 which are in contact with one another, a layer of a poorly defined pattern is formed on a substrate. The same problem is caused in a case in which the opening ends of all the openings 4 are aligned at the same position. Therefore, in the deposition mask according to the present invention, it is necessary that positions of the opening ends of at least three successive openings differ from one another.

If a plurality of openings 4 provided in the sheet of mask foil 2 have the same length L, as illustrated in FIG. 1A, the distance between nodes of steady state vibration is expressed by d=2 L/m (m is a natural number). If the amount of displacement among the opening ends 4E is equal to the steady state vibration frequency λ, the same vibration is caused in the proximal points X1 and Y1 arranged along the width direction of adjoining ribs 5. It is therefore necessary that the amounts of displacement of the positions of the opening ends 4E may be very small, but should not be equal to the integral multiple of the distance between nodes of steady state vibration.

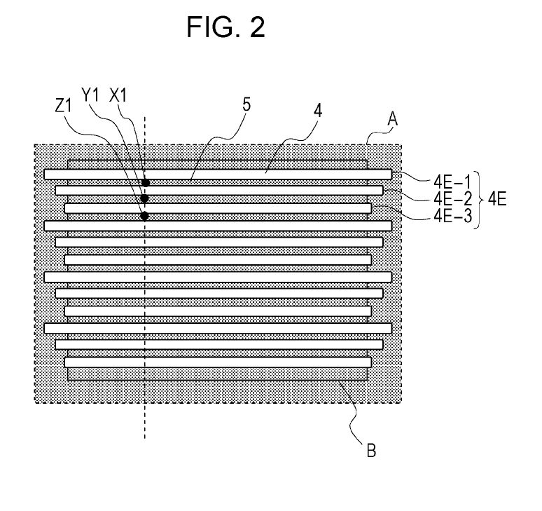

The openings 4 are of the same length in the longitudinal direction in FIG. 1B; if successively arranged at least three openings 4 have different length as illustrated in FIG. 2, it is only necessary that the positions of at least one of the opening ends 4E are different from one another. In this case, since the distance between nodes of steady state vibration between adjoining ribs 5 are different from one another, at the time that steady state vibration is caused in the ribs 5, the amounts of displacement of X1, Y1 and Z1 in the normal direction of a surface of the sheet of mask foil 2 differ from one another as in the case illustrated in FIG. 1A. Desirably, both (rather than any one) of the opening ends 4E are at different positions. This is because, since it is possible that a plurality of openings 4 are arranged symmetrical about a central point of the area A or about a centerline which extends perpendicularly to the longitudinal direction of the area A, tension may be applied uniformly to the openings 4 in longitudinal direction of the sheet of mask foil.

The deposition mask according to the present invention is suitable in various vapor deposition processes and is especially suitable in the manufacture of an organic EL display panel.

### First Example

Hereinafter, examples of a deposition mask 1 having openings illustrated in FIGS. 1A and 1B and a process of manufacturing a plurality of 3.2-inch organic EL display panels from a single substrate using the deposition mask 1 will be described.

A sheet of 40 micrometers-thick mask foil 2 was used. Slit-shaped openings 4 were 40 micrometers in width, 55000 micrometers in opening length and 120 micrometers in opening pitch. As illustrated in FIG. 1B, three openings 4 of which opening ends 4E were displaced by 20 micrometers from one another were defined as a unit and several of them were arranged as repeating units.

Then, a plurality of driving circuits made of TFT and a plurality of lower electrodes arranged along rows and columns was formed on each one of 100 glass substrates. The substrates were conveyed successively to an evaporation apparatus to form a 40 micrometers-thick organic emitting layer on the lower electrodes in a pattern corresponding to each rows of the lower electrodes using the deposition mask 1 illustrated in FIG. 1. The substrates having an organic emitting layer formed thereon were conveyed successively, in the order of the formation of the organic emitting layer, to a sputter apparatus to form upper electrodes each of which continues to each of the patterns of the organic emitting layer; and then conveyed to a CVD apparatus to form protective films made of an inorganic layer on the upper electrodes. Publicly known configurations and materials may be applied to the organic EL display panel. Other than the organic emitting layer, publicly known functional layer(s), such as a hole injection layer and an electron injection layer, may be formed between the lower electrodes and the upper electrodes. The functional layer(s) may be formed using the deposition mask 1 illustrated in FIG. 1 or may be formed as common layer(s) which continue to a plurality of organic emitting layers without using a deposition mask.

The deposition mask 1 was taken out of the evaporation apparatus and the openings 4 were observed: there was no location where the opening was blocked by the ribs 5 in contact with one another. The pattern of the organic emitting layer formed on the substrate was observed: the same pattern as that of the openings 4 formed on the deposition mask was formed and there was no pattern with blocked openings.

### Second Example

This example differs from the first example in that, as illustrated in FIG. 2, three slit-shaped openings 4 having the length of 55000 micrometers, 54980 micrometers and 54960 micrometers were arranged in parallel and displaced by 10 micrometers from one another, were defined as a unit and several of them were arranged as repeating units.

Using the deposition mask, 100 organic EL display panels were manufactured in the same manner as in the first example. The openings 4 of the deposition mask after the formation of the layers were observed: there was no location where the openings were blocked by the ribs 5 in contact with one another. The pattern of the organic emitting layer formed on the substrate was observed: the same pattern as that of the openings 4 formed in the deposition mask was formed and there was no pattern with blocked openings.

### Comparative Example

In a comparative example, 100 organic EL display panels were manufactured in the same manner as in the first example except that a deposition mask (FIG. 3) in which two slit-shaped openings 4 displaced by 20 micrometers from each other were defined as a unit and several of them were arranged as repeating units.

The openings 4 of the deposition mask after the formation of the layers were observed: there was a plurality of locations where the openings 4 were blocked by the ribs 5 in contact with one another in substantially the entire area A. The pattern of the organic emitting layer formed on the substrate was observed: since the mask openings were blocked, the pattern was different from that of the openings 4 formed in the deposition mask and there were defective portions where no organic emitting layer was found. Defective layer patterns emerged at the 20th sheet since formation of layers was started, and after the 50th sheet, almost all the areas A had defective portions.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2010-276175 filed Dec. 10, 2010, which is hereby incorporated by reference herein in its entirety.

What is claimed is:

1. A deposition mask in which a sheet of mask foil provided with a plurality of slit-shaped openings is fixed to a mask frame, wherein ends of successively arranged at least three openings are displaced from one another along the longitudinal direction of the openings.

2. The deposition mask according to claim 1, wherein both ends of successively arranged at least three openings are displaced from one another along the longitudinal direction of the openings.

3. The deposition mask according to claim 1, wherein the successively arranged at least three openings are different in length from one another.

4. A method of manufacturing an organic EL display panel, comprising: forming a driving circuit on a substrate; and forming an organic emitting layer on the substrate using the deposition mask according to claim 1.

5. An organic EL display panel comprising:
lower electrodes arranged along rows and columns;
organic emitting layers; and
upper electrodes,
wherein:
each of the organic emitting layers is provided on each of the lower electrodes via openings of a deposition mask; and
at least one of column-direction ends of successively arranged at least three organic emitting layers are displaced from one another along the column direction.
